(19) United States
(12) Patent Application Publication
(10) Pub. No.: US 2025/0218854 A1
(43) Pub. Date: Jul. 3, 2025

(54) SUBSTRATE PROCESSING APPARATUS

(71) Applicant: SEMES CO., LTD., Cheonan-si (KR)

(72) Inventors: In Ki JUNG, Hwaseong-si (KR); Jun Ho SONG, Hwaseong-si (KR); Se Hoon OH, Cheonan-si (KR); Seung Joo CHOI, Incheon (KR); Jeong Hyup YU, Hwaseong-si (KR)

(73) Assignee: SEMES CO., LTD., Cheonan-si (KR)

(21) Appl. No.: 19/005,394

(22) Filed: Dec. 30, 2024

(30) Foreign Application Priority Data
Dec. 28, 2023 (KR) 10-2023-0195384

(51) Int. Cl. H01L 21/687; B08B 3/04; H01L 21/67

(52) U.S. Cl. CPC H01L 21/68721; B08B 3/041; H01L 21/67051

(57) ABSTRACT

A substrate processing apparatus includes a support unit capable of driving a guide ring unit and a chuck pin at the same time. According to an example embodiment, the vertical movement of a spin chuck and the horizontal movement of the chuck pin may be performed simultaneously.

### CROSS-REFERENCE TO RELATED APPLICATIONS

This application claims priority to and the benefit of Korean Patent Application No. 10-2023-0195384 filed in the Korean Intellectual Property Office on Dec. 28, 2023, the entire contents of which are incorporated herein by reference.

### TECHNICAL FIELD

The present invention relates to a substrate processing apparatus, and more specifically, to a substrate processing apparatus including a support unit capable of driving a guide ring unit and a chuck pin at the same time.

### BACKGROUND ART

A semiconductor process includes a process of cleaning a thin film, foreign matter, particles, and the like on a substrate. The cleaning process is performed by placing a substrate on a spin chuck and supplying a treatment liquid to the upper surface of the substrate in a state in which the spin chuck is rotated. In this case, since the thin film and the like deposited on the bottom surface of the substrate acts as a foreign material in the subsequent process, a cleaning process is also performed on the lower surface of the substrate in order to remove foreign substances, such as the unnecessary thin film. When the bottom surface of the substrate is cleaned, a back nozzle for spraying the treatment liquid toward the bottom surface of the substrate is provided.

During the rotation of the spin chuck, the treatment liquid is scattered. The scattered liquid is recovered by a cup surrounding the spin chuck for contamination prevention and recycling or disposal of the wafer. Since the treatment liquid is provided in various types, the treatment liquids need to be separated and recovered by using different cups when recovering the treatment liquid. However, in order to avoid the interference between the spin chuck and the cup generated when the substrate is loaded in and unloaded from the spin chuck, the spin chuck and the cup are spaced apart at regular intervals. Due to this separation, there is a problem that the treatment liquid scattered from the spin chuck is not recovered through an appropriate cup.

Accordingly, a guide ring adjacent to the spin chuck may be provided to guide the scattered treatment liquid to an appropriate cup. However, when a guide ring is provided, there is a problem that it is difficult to transfer the substrate due to interference between the guide ring and the substrate. In addition, when a back nozzle for discharging a treatment liquid to a lower surface of a substrate is provided in the spin chuck, it is difficult to transfer the substrate by adjusting the height of the spin chuck.

### SUMMARY OF THE INVENTION

The present invention has been made in an effort to provide a substrate processing apparatus capable of resolving interference between a transfer robot and a guide ring when a substrate is loaded into a spin chuck or is unloaded from the spin chuck.

The present invention has also been made in an effort to provide a substrate processing apparatus capable of transferring a substrate without adjusting a height of a spin chuck in the substrate processing apparatus that provides a guide ring and a back nozzle.

The present invention has also been made in an effort to provide a substrate processing apparatus capable of improving a separation recovery rate of a plurality of treatment liquids.

The problem to be solved by the present invention is not limited to the above-mentioned problems, and the problems not mentioned will be clearly understood by those skilled in the art from the descriptions below.

An exemplary embodiment of the present invention provides an apparatus of processing a substrate, the apparatus comprising: a cup body having a treatment space therein; a support unit for supporting a substrate within said treatment space; and a guide ring unit located in the treatment space, surrounding the substrate placed on the support unit, and guiding a treatment liquid scattered from the substrate to the cup body; a liquid supply unit for supplying the treatment liquid to the substrate; and a driver, wherein the support unit includes: a spin chuck on which the substrate is placed and which is rotatable; and a chuck pin provided to the spin chuck and supporting the substrate on a side portion of the substrate, the guide ring unit is provided to be movable relative to the spin chuck in an up and down direction, the chuck pin is provided to be movable between a support position supporting an end of the substrate placed on the spin chuck and a spaced position spaced apart from the end of the substrate placed on the spin chuck, and the driver moves the guide ring relative to the spin chuck and simultaneously may moves the chuck pin between the support position and the spaced position.

According to the exemplary embodiment of the present invention the guide ring is movable between a process position and a waiting position, the process position is a position where a relative height with respect to the spin chuck is higher than the waiting position, and the chuck pin may be provided to move from the spaced position to the support position when the guide ring is moved from the waiting position to the process position.

According to the exemplary embodiment of the present invention the chuck pin may be provided to move from the support position to the spaced position when the guide ring is moved from the process position to the waiting position.

According to the exemplary embodiment of the present invention the cup body includes: an inner cup; an intermediate cup surrounding the inner cup; and an outer cup surrounding the intermediate cup, and the guide ring may be provided to guide the treatment liquid scattered from the substrate to a space selected from a space between the inner cup and the intermediate cup and a space selected between the intermediate cup and the outer cup.

According to the exemplary embodiment of the present invention the apparatus may further include a pin drive link connected to the driver, wherein the chuck pin is moved by the pin drive link, the pin drive link may include: a first link to which the chuck pin is coupled; and a second link pivotally coupled to the first link and installed in the guide ring.

According to the exemplary embodiment of the present invention the apparatus may further include an elastic member, wherein the elastic member is installed under the guide ring support and is provided in a compressed state at the process position to may apply elastic force toward the guide ring.

According to the exemplary embodiment of the present invention the guide ring includes: an upper ring; a lower ring facing the upper ring in an up and down direction; and an intermediate ring disposed between the upper ring and the lower ring, and the upper ring, the intermediate ring, and the lower ring may be fixed to each other by a fixing rod.

According to the exemplary embodiment of the present invention the driver and the guide ring unit may be separably provided.

According to the exemplary embodiment of the present invention the treatment liquid is provided as a first treatment liquid or a second treatment liquid different from the first treatment liquid, the liquid supply unit includes: a first nozzle for discharging the first treatment liquid to an upper surface of the substrate; and a second nozzle for discharging the second treatment liquid to a lower surface of the substrate, and the first treatment liquid and the second treatment liquid may be separated and recovered by the guide ring.

An exemplary embodiment of the present invention provides an apparatus of processing a substrate, the apparatus comprising: a cup body having a treatment space therein; a support unit for supporting a substrate within said treatment space; and a guide ring unit located in the treatment space, surrounding the substrate placed on the support unit, and guiding a treatment liquid scattered from the substrate to the cup body; a liquid supply unit for supplying the treatment liquid to the substrate; and a first driver for driving the guide ring, wherein the guide ring unit includes: a guide ring for guiding a treatment liquid scattered from the substrate to the cup body; and a guide ring support in which the guide ring is installed and to which the first driver is connected, the support unit includes: a spin chuck on which the substrate is placed and which is rotatable; and a chuck pin provided to the spin chuck and supporting the substrate on a side portion of the substrate; and a pin drive link which is coupled with the chuck pin, and which drives the chuck pin to approach or move away from the substrate supported by the spin chuck, and the pin drive link may operates in conjunction with driving of the first driver.

According to the exemplary embodiment of the present invention the chuck pin moves in a direction approaching the substrate placed on the spin chuck when the guide ring is raised, and may moves in a direction away from the substrate placed on the spin chuck when the guide ring is lowered.

According to the exemplary embodiment of the present invention the pin drive link includes: a first link coupled with the chuck pin; and a second link connected to the first link and installed on the guide ring support, and the first link and the second link, and the second link and the guide ring support may be pivotally coupled to each other.

According to the exemplary embodiment of the present invention the apparatus may further include an elastic member, wherein the elastic member may be installed under the guide ring support and provided in a compressed state at the process position to apply elastic force toward the guide ring support.

According to the exemplary embodiment of the present invention the support unit includes: a rotating shaft for supporting the spin chuck at a center of a bottom surface of the spin chuck; a second driver for providing rotational force to the rotating shaft; a first plate to which the guide ring support is connected and which is provided to surround the rotating shaft; and a second plate connected to the first driver and provided to surround the first plate, and the first plate is formed with a first protrusion and a first groove, the second plate is formed with a second groove corresponding to a shape and a position of the first protrusion, and a second protrusion corresponding to a shape and a position of the first groove, when viewed from above, the first groove and the second groove are provided so that partial areas thereof overlap as the first plate rotates, and when the spin chuck is rotated, the first plate and the second plate may be spaced apart from each other.

According to the exemplary embodiment of the present invention the chuck pins are provided in plural, the plurality of chuck pins is coupled to the plurality of first links, respectively, the plurality of first links is connected to the plurality of second links, respectively, and the plurality of second links may be installed on the guide ring support.

According to the exemplary embodiment of the present invention the treatment liquid is provided as a first treatment liquid or a second treatment liquid different from the first treatment liquid, the cup body includes: an inner cup surrounding the support unit; an intermediate cup surrounding the inner cup; and an outer cup surrounding the intermediate cup, the inner cup, the intermediate cup, and the outer cup are stacked on each other, the inner cup provides a first inlet through which the second treatment liquid is scattered, the inner cup and the intermediate cup are combined with each other to provide a second inlet through which the first treatment liquid or the second treatment liquid is scattered, the intermediate cup and the outer cup are combined with each other to provide a third inlet through which the first treatment liquid is scattered, the guide ring includes: an upper ring; a lower ring facing the upper ring in an up and down direction; and an intermediate ring disposed between the upper ring and the lower ring, and the upper ring, the intermediate ring, and the lower ring are fixed to each other by a fixing rod, and may be positioned so that during the treatment of the substrate, the first treatment liquid or the second treatment liquid are scattered to the first inlet, the second inlet, or the third inlet.

According to the exemplary embodiment of the present invention the liquid supply unit may include: a first nozzle for discharging the first treatment liquid to an upper surface of the substrate; and a second nozzle for discharging the second treatment liquid to a lower surface of the substrate.

An exemplary embodiment of the present invention provides an apparatus of processing a substrate, the apparatus comprising: a cup body having a treatment space therein; a support unit for supporting a substrate within said treatment space; and a guide ring unit located in the treatment space, surrounding the substrate placed on the support unit, and guiding a treatment liquid scattered from the substrate to the cup body; a liquid supply unit including a first nozzle discharging a first treatment liquid to an upper surface of the substrate, and a second nozzle discharging a second treatment liquid to a bottom surface of the substrate, and a drive unit for driving the guide ring unit and the support unit, wherein the support unit includes: a spin chuck on which the substrate is placed and which is rotatable; and a chuck pin provided to the spin chuck and supporting the substrate on a side portion of the substrate; a rotating shaft for supporting the spin chuck at a center of a bottom surface of the spin chuck; and a pin drive link which is coupled with the chuck pin, and which drives the chuck pin to approach or move away from the substrate supported by the spin chuck, and the guide ring unit includes: a guide ring for guiding a treatment liquid scattered from the substrate to the cup body; and a guide ring support in which the guide ring is installed and to which a first driver is connected, the drive unit includes: a first driver for driving the guide ring unit; a second driver for driving the support unit; a first plate to which the guide ring support is connected and which is provided to surround the rotating shaft; and a second plate connected to the first driver and provided to surround the first plate, and the pin drive link includes: a first link coupled with the chuck pin; and a second link connected to the first link and installed on the guide ring support, the first link and the second link are provided to pivot at a connection point where the first link and the second link are connected, the second link and the guide ring support are provided to pivot at an installation point where the second link is installed on the guide ring support, when the guide ring unit is lowered, the chuck pin moves in a direction away from the substrate, and when the guide ring unit is raised, the chuck pin moves in a direction close to the substrate, the first plate is formed with a first protrusion and a first groove, the second plate is formed with a second groove corresponding to a shape and a position of the first protrusion, and a second protrusion corresponding to a shape and a position of the first groove, and when viewed from above, the first groove and the second groove may be provided so that partial areas thereof overlap as the first plate rotates.

According to the exemplary embodiment of the present invention the apparatus may further include an elastic member, wherein the elastic member may be installed under the guide ring support and provided in a compressed state at the process position to apply elastic force toward the guide ring support.

According to the exemplary embodiment of the present invention the cup body includes: an inner cup surrounding the support unit; an intermediate cup surrounding the inner cup; and an outer cup surrounding the intermediate cup, the inner cup, the intermediate cup, and the outer cup are stacked on each other, the inner cup provides a first inlet through which the second treatment liquid is scattered, the inner cup and the intermediate cup are combined with each other to provide a second inlet through which the first treatment liquid or the second treatment liquid is scattered, the intermediate cup and the outer cup are combined with each other to provide a third inlet through which the first treatment liquid is scattered, the guide ring includes: an upper ring; a lower ring facing the upper ring in an up and down direction; and an intermediate ring disposed between the upper ring and the lower ring, and the upper ring, the intermediate ring, and the lower ring are fixed to each other by a fixing rod, and may be positioned so that during the treatment of the substrate, the first treatment liquid or the second treatment liquid are scattered to the first inlet, the second inlet, or the third inlet.

According to the exemplary embodiment of the present invention, the vertical movement of the spin chuck and the horizontal movement of the chuck pin may be performed simultaneously.

Further, according to the exemplary embodiment of the present invention, it is possible to eliminate the interference between the transfer robot and the guide ring when the substrate is loaded in or unloaded from the spin chuck.

Furthermore, according to the exemplary embodiment of the present invention, it is possible to improve the separation recovery rate of a plurality of treatment liquids.

Furthermore, according to the exemplary embodiment of the present invention, it is possible to transfer the substrate without adjusting the height of the spin chuck in the substrate processing apparatus that provides the guide ring and the back nozzle.

The effects of the invention are not limited to those described above, and those not described will be apparent to those skilled in the art from this specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The attached drawings may be exaggerated in the various dimensions of the drawings for clarity.

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram illustrating a support unit and a guide ring unit in the liquid treating chamber of FIG. 2 in more detail.

FIG. 4 is a diagram illustrating a movement direction of a pin drive link when a chuck pin moves from a spaced position to a support position.

FIG. 5 is a diagram illustrating an exemplary embodiment of the pin drive link when the chuck pin of FIG. 3 is at the spaced position.

FIG. 6 is a diagram illustrating a state viewed from above when a first plate and a second plate of FIG. 3 are at a first position.

FIG. 7 is a diagram illustrating a state viewed from above when the first plate and the second plate of FIG. 3 are at a second position.

FIG. 8 is a diagram illustrating the appearance of the support unit and the guide ring unit when the guide ring unit is located at a waiting position and the chuck pin is located at the spaced position.

FIG. 9 is a diagram illustrating the support unit and the guide ring unit when the guide ring unit is located at a process position and the chuck pin is located at the support position.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to devices used of processing other types of substrates other than wafers as treatment targets.

Hereinafter, an exemplary embodiment of the present invention will be described with reference to the accompanying drawings.

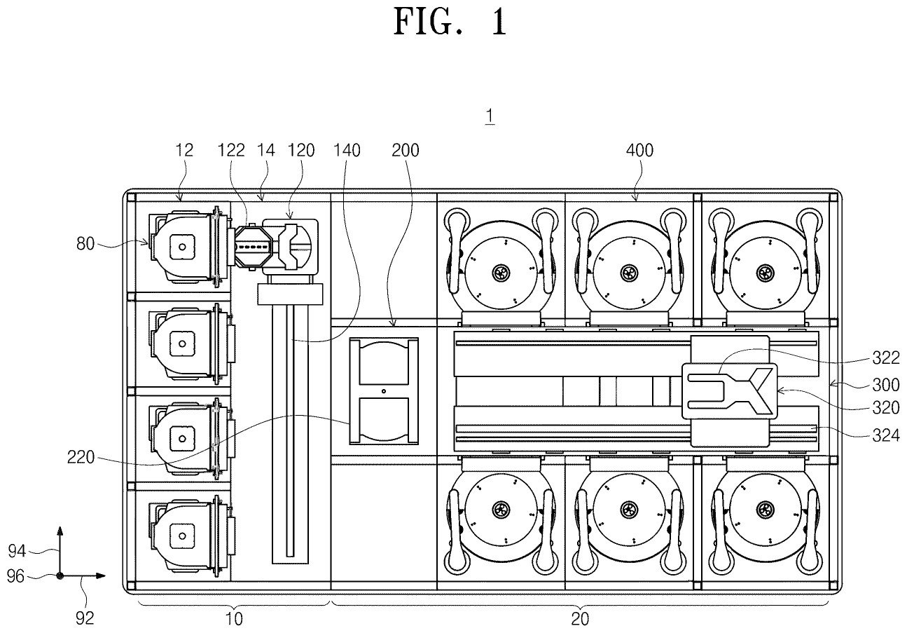

FIG. 1 is a top plan view schematically illustrating a substrate processing apparatus according to an exemplary embodiment of the present invention.

Referring to FIG. 1, the substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are arranged is referred to as a first direction 92, a direction perpendicular to the first direction 92 when viewed from the top is referred to as a second direction 94, and a direction perpendicular to both the first direction 92 and the second direction 94 is referred to as a third direction 96.

The index module 10 transfers the substrate W from a container 80 in which the substrate W is received to the treating module 20, and receives the substrate W treated by the treating module 20 to the container 80. A longitudinal direction of the index module 10 is provided in the second direction 94. The index module 10 includes a load port 12 and an index frame 14. With respect to the index frame 14, the load port 12 is located at a side opposite to the treating module 20. The containers 80 in which the substrates W are received are placed on the load ports 12. A plurality of load ports 12 may be provided, and a plurality of load ports 12 may be disposed along the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 having a longitudinal direction provided in the second direction 94 is provided in the index frame 14, and the index robot 120 may be provided to be movable on the guide rail 140. The index robot 120 includes a hand 122 on which the substrate W is placed, and the hand 122 may be provided to be movably forwardly and backwardly, rotatable around the third direction 96 and movable along the third direction 96. A plurality of hands 322 are provided to be spaced apart in the up and down direction, and the hands 322 may move forward and backward independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process for liquid-treating the substrate W by supplying a liquid onto the substrate W. The transfer chamber 300 transfers the substrate W between the buffer unit 200 and the liquid treating chamber 400.

A longitudinal direction of the transfer chamber 300 may be provided in the first direction 92. The buffer unit 200 may be disposed between the index module 10 and the transfer chamber 300. A plurality of liquid treating chambers 400 may be provided and may be disposed at a side portion of the transfer chamber 300. The liquid treating chamber 400 and the transfer chamber 300 may be disposed along the second direction 94. The buffer unit 200 may be located at one end of the transfer chamber 300.

According to the example, the liquid treating chambers 400 are respectively disposed on both sides of the transfer chamber 300. At one side of the transfer device 300, the liquid treating devices 400 may be provided in an arrangement of A×B (each of A and B is 1 or a natural larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the up and down direction, and the hands 322 may move forward and backward independently of each other.

The buffer unit 200 includes a plurality of buffers 220 on which the substrate W is placed. The buffers 220 may be disposed to be spaced apart from each other along the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

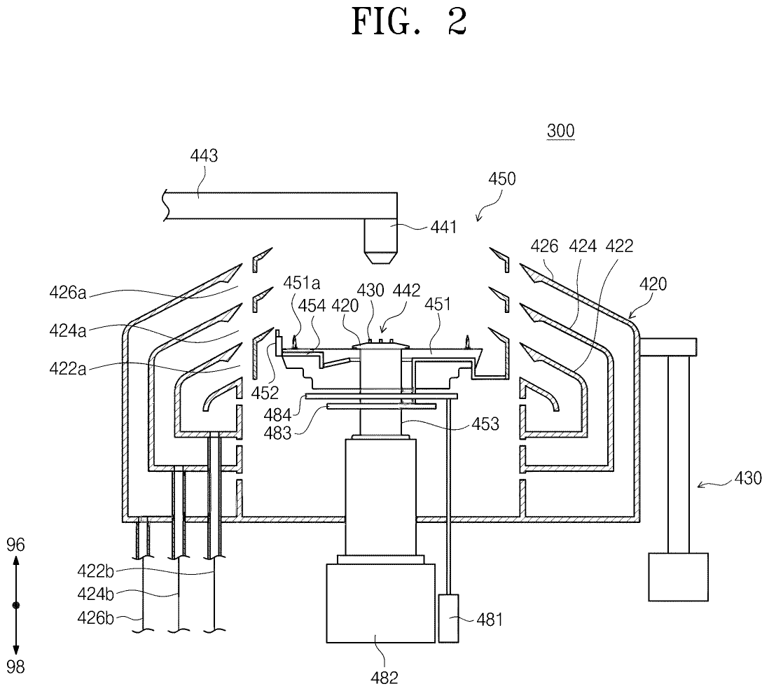

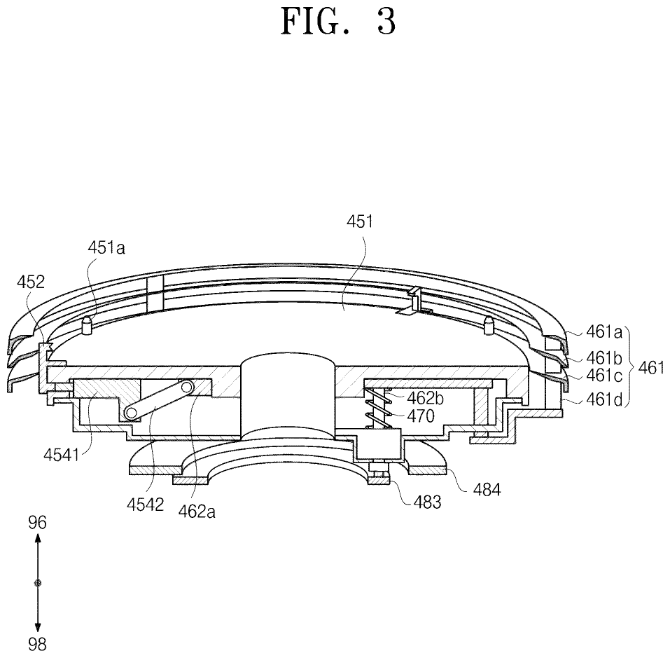

FIG. 2 is a diagram schematically illustrating an exemplary embodiment of the liquid treating chamber of FIG. 1, and FIG. 3 is a diagram illustrating the support unit and the guide ring unit in the liquid treating chamber of FIG. 2 in more detail. Referring to FIGS. 2 and 3, the liquid treating chamber 400 includes a housing 410, a cup body 420, a lifting unit 430, a liquid supply unit 440, a support unit 450, a guide ring unit 460, a drive unit 480, and a controller.

The housing 410 is provided in a generally rectangular parallelepiped shape. The housing provides an interior space. The components to be described below may be disposed in the housing 410. An opening (not illustrated) provided as a passage of the substrate W may be formed in the side portion of the housing 410.

The cup body 420 has a treatment space with an open top, and the substrate W is liquid-treated in the treatment space. A relative height of the cup body 420 between the support unit 450 is adjusted by the lifting unit 430.

According to the example, the cup body 420 includes a plurality of cups 422, 424, and 426. Each of the cups 422, 424, and 426 has a recovery space of recovering the liquid used for the treatment of the substrate. Each of the cups 422, 424, and 426 is provided in a ring shape surrounding the support unit 450. When the liquid treatment process is in progress, the treatment liquid scattered by the rotation of the substrate W is introduced into the recovery space through inlets 422a, 424a, and 426a of the respective cups 422, 424, and 426. According to the exemplary embodiment, the cup body 420 includes an inner cup 422, an intermediate cup 424, and an outer cup 426. The inner cup 422 is disposed to surround the support unit 430, the intermediate cup 424 is disposed to surround the inner cup 422, and the outer cup 426 is disposed to surround the intermediate cup 424. A second inlet 424a, which introduces the liquid into the intermediate cup 424, may be positioned above a first inlet 422a, which introduces the liquid into the inner cup 422, and a third inlet 426a, which introduces the liquid into the outer cup 426, may be positioned above the second inlet 424a. A first discharge pipe 422b through which the treatment liquid recovered through the first inlet 422a is discharged may be connected to the bottom of the inner cup 422. A second discharge pipe 424b through which the treatment liquid recovered through the second inlet 424a is discharged may be connected to the bottom of the intermediate cup 424. A third discharge pipe 426b through which the treatment liquid recovered through the third inlet 426a is discharged may be connected to the bottom of the outer cup 426.

The lifting unit 430 moves the cup body 420 in the up and down direction. By the up and down movement of the cup body 420, a relative height between the cup body 420 and the substrate W is changed. Accordingly, since the cups 422, 424, and 426 for recovering the treatment liquid are changed according to the type of the liquid supplied to the substrate W, the liquids may be separated and recovered.

The liquid supply unit 440 includes a first nozzle 441 and a second nozzle 442. The first nozzle 441 supplies a first treatment liquid to the upper surface of the substrate W supported by the chuck pin 432. The first nozzle 441 is supported by a nozzle support 443. The nozzle support 443 moves the nozzle between a process position and a waiting position. In the process position, the first nozzle 441 supplies the first treatment liquid to the substrate W placed on the spin chuck 451, and the nozzle 441 which has completed supplying the first treatment liquid waits in the waiting position. According to an exemplary embodiment, the first treatment liquid may be chemical or ultrapure. The second nozzle 442 may be provided as a back nozzle. When the second nozzle 442 is provided as a back nozzle, the second nozzle 442 is installed on the upper surface of the spin chuck 451 to be described later. Also, a through hole for installing the back nozzle may be formed in the center of the spin chuck 451. The second nozzle 442 supplies a second treatment liquid to the bottom surface of the substrate W supported by the chuck pin 432. According to the example, the second treatment liquid may be ultrapure.

The support unit 450 supports the substrate W in the treatment space. The support unit 450 includes a spin chuck 451, a chuck pin 452, a rotating shaft 453, and a pin drive link 454.

The spin chuck 451 supports the substrate W. The upper surface of the spin chuck 451 is provided in a generally circular shape and may have a larger diameter than the substrate W. A support pin 451a for supporting the rear surface of the substrate W is provided in a central portion of the spin chuck 451. A plurality of support pins 451a is provided. The support pins 451a are arranged to have an annular ring shape as a whole by combination thereof. The support pin 452a is provided such that an upper end thereof protrudes from the spin chuck 451 so that the substrate W is spaced apart from the spin chuck 451 by a predetermined distance.

The chuck pin 452 supports a side portion of the substrate W so that the substrate W is not separated from the support unit 450 when the substrate W is rotated. The chuck pin 452 is provided at an edge portion of the spin chuck 451. The chuck pin 452 is disposed to be farther from the center of the spin chuck 451 than the supporting pin 451a. The chuck pin 452 is provided to protrude upwardly from the spin chuck 451. A plurality of chuck pins 452 is provided. The chuck pin 452 is provided to be movable between a support position C1 and a spaced position C2. The support position C1 is a position at which the chuck pin 452 supports the end of the substrate W placed on the spin chuck 452. The chuck pin 452 is located at the support position C2 during the performance of the process on the substrate W. The spaced position C1 is a position at which the chuck pin 452 is spaced apart from the substrate W. When the substrate W is loaded in or unloaded from the support unit 450, the chuck pin 452 is located at the spaced position C1. According to the example, the chuck pin 452 may be provided to linearly move between the support position C1 and the spaced position C2.

The rotating shaft 453 is provided to be rotatable by a second driver 452. The rotating shaft 453 is fixedly coupled to the center of the bottom surface of the spin chuck 451. Accordingly, the second driver 456 to be described later may rotate the spin chuck 451.

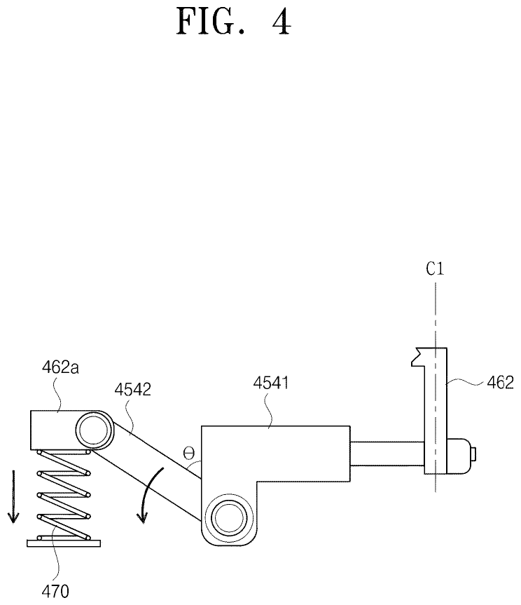

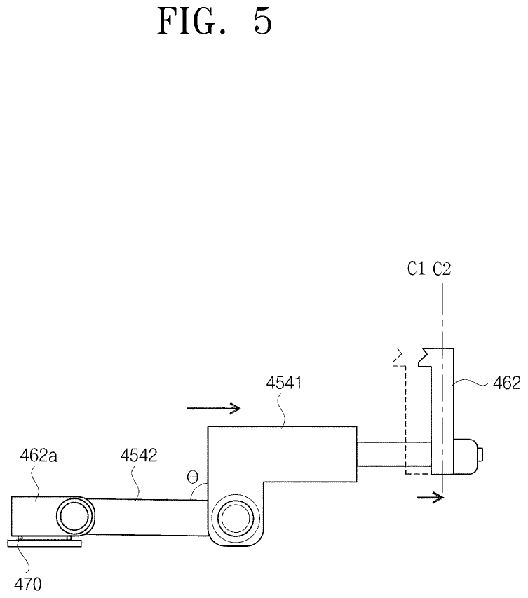

FIG. 4 is a diagram illustrating a movement direction of the pin drive link when the chuck pin moves from the spaced position to the support position, and FIG. 5 is a diagram illustrating an exemplary embodiment of the pin drive link when the chuck pin of FIG. 3 is at the support position. Referring to FIGS. 4 and 5, the pin drive link 454 moves the chuck pin 452 between the support position C1 and the spaced position C2. The pin drive links 454 are provided in the number corresponding to the number of chuck pins 452. The pin drive link 454 includes a first link 4541 and a second link 4542.

The first link 4541 includes a portion parallel to the first direction 92 (hereinafter, “horizontal portion 4541a”) and a portion parallel to the third direction 96 (hereinafter, “vertical portion 4541b”). According to the example, the first link 4541 may be provided in an “1” shape. An end of the horizontal portion 4541a and an end of the vertical portion 4541b may be fixedly coupled or integrally provided with each other. The chuck pin 452 is coupled to the other end of the horizontal portion 4541a. Also, the horizontal portion 4541a may be installed in the horizontal movement guide 455 provided in the spin chuck 451. The second link 4542 is coupled to the other end of the vertical portion 4542a.

The second link 4542 may be provided as a connection link. The second link 4542 is coupled to a guide ring support 462 to be described later. The first link 4541, the second link 4542, and the second link 4542 and the guide ring support 462 may be pivotally coupled, respectively. Accordingly, when the guide ring support 462 moves in the third direction 96 or a fourth direction 98 (hereinafter, referred to as “up and down movement”), the second link 4542 is also moved together, but since the vertical position of the first link 4541 is fixed by the guide 455, the second link 4542 may horizontally move the first link 4541 while performing the pivot motion. According to the example, the spaced position C1 may be a position at which the guide ring support 462 is located at the lowermost portion inside the spin chuck 451. Also, the spaced position C1 may be a position at which an angle θ between the first link 4541 and the second link 4542 is maximum. The support position C2 may be a position at which the guide ring support 462 is located at the topmost portion inside the spin chuck 451. Also, the support position C2 may be a position at which an angle θ between the first link 4541 and the second link 4542 is minimum.

Referring back to FIGS. 2 and 3, the guide ring unit 460 may include a guide ring 461 and a guide ring support 462. The guide ring 461 may be provided adjacent to the spin chuck 451. The guide ring 461 may be provided to surround the spin chuck 451. The guide ring 461 may be provided to be inclined downwardly in a direction away from the spin chuck 451. In addition, an end of the guide ring 461 may be provided to be inclined again toward the fourth direction 98. Accordingly, the guide ring may be provided to be inclined in a two-stage inclined shape.

The guide ring 461 includes an upper ring 461a, an intermediate ring 461b, a lower ring 461c, and a fixing rod 461d. The upper ring 461a, the intermediate ring 461b, and the lower ring 461c are provided to overlap when viewed from above. The upper ring 461a is located above the intermediate ring 461b. The intermediate ring 461b is located between the upper ring 461a and the lower ring 461c. The lower ring 461c is located at a position facing the upper ring in the up and down direction. The lower ring 461c, the intermediate ring 461b, and the upper ring 461a are located in the third direction 96 in the order of the lower ring 461c, the intermediate ring 461b, and the upper ring 461a. The upper ring 461a, the intermediate ring 461b, and the lower ring 461c are coupled to the fixing rod 461d. The fixing rod 461d may be provided to penetrate the edge regions of the upper ring 461a, the intermediate ring 461b, and the lower ring 461c in the third direction 96. Also, the guide ring support 462 may be connected to the fixing rod 461d.

The guide ring support 462 is located below the guide ring 461. The guide ring 461 is installed on the guide ring support 462 by means of the fixing rod 461d. The guide ring support 462 penetrates the lower end of the spin chuck 451 and is inserted into the spin chuck 451. The second link 4542 and the guide ring support 462 are pivotally coupled to the inside of the spin chuck 451. According to the example, the guide ring support 462 has a ring-shaped structure 462a that may be located at the center of the inside of the spin chuck 451, and a plurality of second links 4542 may be pivotally coupled to the ring-shaped structure 462a. An extension portion 462b is formed on the guide ring support 462. The extension portion 426b has a shape extending in the fourth direction 98 from a portion of the guide ring support 462 inserted into the support plate 451. The extension portion 462b is coupled to a first driver 481. The guide ring support 462 may include a plurality of extension portions 462b. When a plurality of extension portions 462b are provided, the extension portion 462b and the pin drive link 454 may cross each other within the spin chuck 451. In the example, three pin drive links 454 and three extension portions 462b are provided, respectively, and when viewed from above, the pin drive links 454 and the extension portions 462b are arranged in 120 degrees, and the extension portion 462b-1 is disposed between the pin drive link 454-1 and the pin drive link 454-2, and the pin drive link 454-2 may be disposed between the extension portion 462b-1 and the extension portion 462b-2. In addition, an elastic member 470 may be installed in a portion 462b existing inside the spin chuck 451 among the portions extending in the fourth direction.

The elastic member 470 may be provided in a compressed state in the fourth direction 98. One end of the elastic member 470 may be provided to be in contact with the lower wall of the spin chuck 451. The other end of the elastic member 470 may be provided to be in contact with the guide ring support 462. According to the example, the elastic member 470 may be provided as a spring, and the extension portion 462b may be inserted into the spring. Accordingly, the guide ring unit 460 may be lifted in the third direction 96 by elastic force of the elastic member 470.

The drive unit 480 may include a first driver 481 and a second driver 482. The first driver 481 is connected to the guide ring support 462. The guide ring support 462 may be vertically moved by the first driver 481. According to the example, the first driver 481 may be provided as a cylinder. The first driver 481 moves the guide ring unit 460 between a waiting position P1 and a process position P2. The waiting position P1 may be a position where the guide ring unit 460 is lowered. The waiting position P1 may be a position where a relative height of the spin chuck 451 is lower. The waiting position P1 may be a position where interference does not occur with the transfer robot 320 that transfers the substrate W while the substrate W is loaded in or unloaded from the spin chuck 451. The process position P2 may be a position where the guide ring unit 460 is raised. The process position P2 may be a position having a relative height with respect to the spin chuck 451 higher than that of the waiting position P1. The process position P2 is a position at which the treatment liquid scattered while the substrate W is being treated may be separated and guided. The second driver 482 provides rotational force to the rotating shaft 483. Accordingly, while the substrate W supported by the spin chuck 481 rotates, the liquid treatment may be performed.

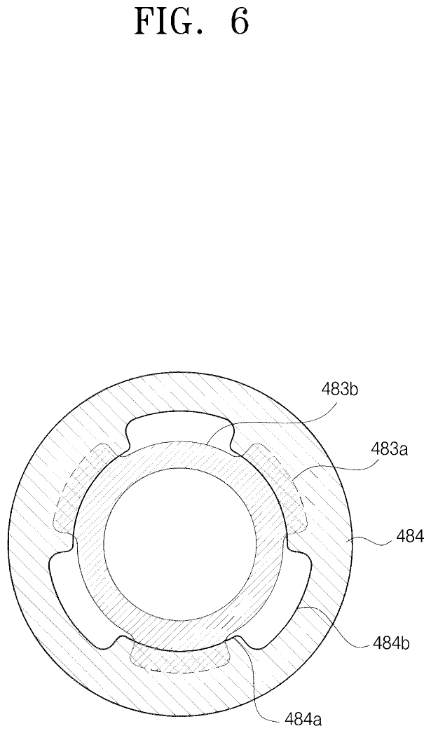

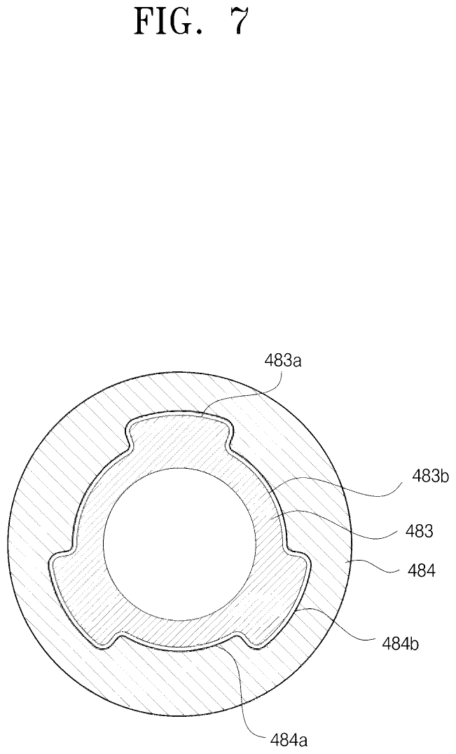

The drive unit 480 may further include a first plate 483 and a second plate 484. In this case, the first plate 483 may be connected to the guide ring support 462, and the second plate 484 may be connected to the first driver 482. The first plate 483 may have a shape surrounding the rotating shaft 453. The first plate 483 may be provided as a ring-shaped plate. A first protrusion 483a and a first groove 483a may be formed at an outer side of the first plate 483. A plurality of first protrusions 483a and a plurality of first grooves 483a may be provided. The second plate 484 may be provided as a ring-shaped plate. The second plate 484 may have a shape surrounding the first plate. The second plate 484 may be located above the first plate 483. The second plate 484 may be provided to be spaced apart from the first plate 483 in the third direction 96. A second groove 484a may be formed at the inner side of the second plate 484 in the position and shape corresponding to the first protrusion. Also, the second protrusion 484a may be formed in the position and shape corresponding to the first groove 483a. Accordingly, the first plate 483 and the second plate 484 may form a key groove structure. The first plate 483 may rotate together with the spin chuck 451 by the second driver 482. FIG. 6 is a diagram illustrating a state viewed from above when the first plate and the second plate of FIG. 3 are at the first position, and FIG. 7 is a diagram illustrating a state viewed from above when the first plate and the second plate of FIG. 3 are at the second position. Referring to FIGS. 6 and 7, as the first plate 483 rotates, the first protrusion 483a and the second protrusion 484a may partially or entirely overlap each other. This position is defined as a first position R1. Also, a position where the first protrusion 483a and the second protrusion 484a do not overlap is defined as a second position R2. According to the exemplary embodiment, the first plate 483 and the second plate 484 may always be located at the first position R1 except when the spin chuck 451 is managed or replaced.

Hereinafter, a process of loading the substrate W, treating the substrate W, and unloading the substrate W by using the substrate processing apparatus according to the exemplary embodiment of the present invention will be described.

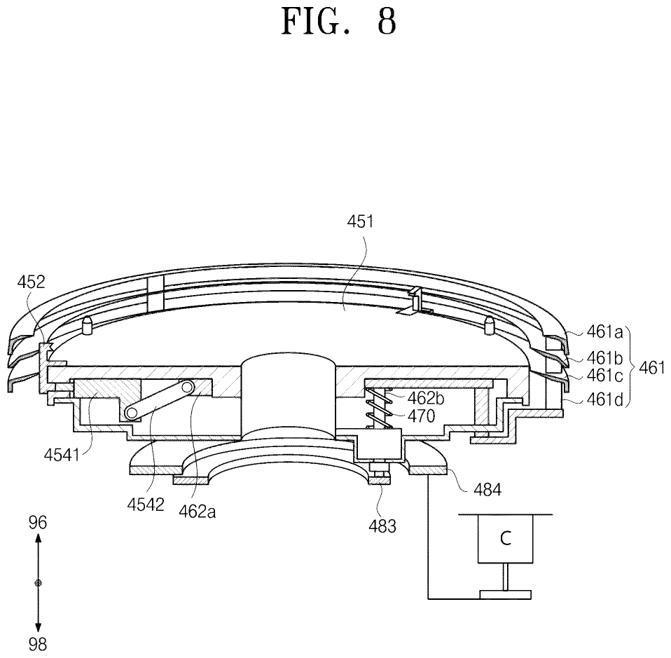

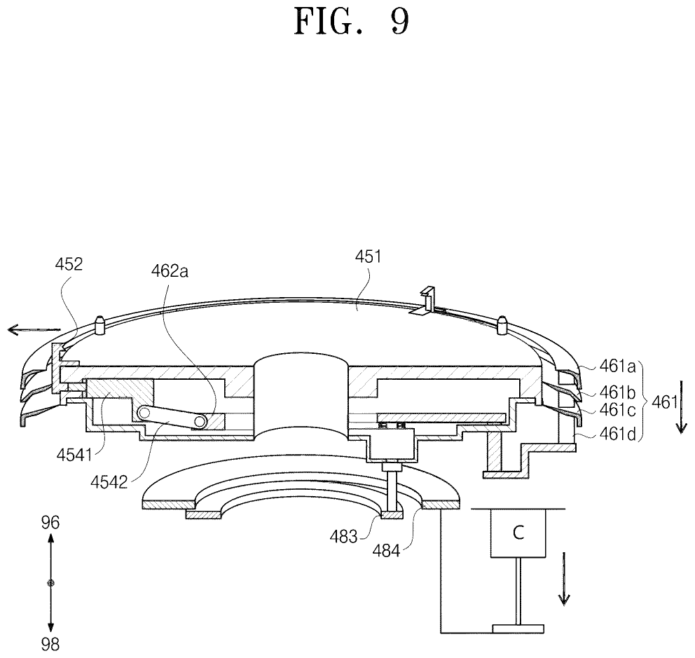

FIG. 8 is a diagram illustrating the appearance of the support unit and the guide ring unit when the guide ring unit is located at a waiting position and the chuck pin is located at the spaced position, and FIG. 9 is a diagram illustrating the support unit and the guide ring unit when the guide ring unit is located at the process position and the chuck pin is located at the support position. Referring to FIGS. 8 and 9, the first plate 483 is rotated to be positioned at the first position R1 in order to load the substrate W. The first driver 481 moves the second plate 484 in the fourth direction 98. The second plate 484 is in contact with the first plate 434 while moving in the fourth direction 98. Since the first protrusion 483a and the second protrusion 484a overlap each other when viewed from above, the first plate 483 may be lowered when the second plate 484 is lowered in the fourth direction 98. When the first plate is lowered, the guide ring support 462 and the guide ring 461 installed on the guide ring support 462 are also lowered. When the guide ring support 462 is lowered, the second link 4542 coupled to the guide ring support 462 is also lowered. According to the example, the second link 4542 may be rotated in the clockwise direction around a coupling portion with the first link 4541. Simultaneously, the second link 4542 pushes the first link 4541 in a direction away from the spin chuck 451. The chuck pin 452 is spaced apart from the spin chuck 451 by the movement of the first link 4541. As a result, the guide ring unit 460 is positioned at the waiting position P1, and the chuck pin 452 is positioned at the spaced position C2. Thereafter, the substrate W is loaded. The substrate W is supported by the support pin 451a on the spin chuck 451.

When the substrate W is loaded, the first driver 481 moves the first plate 483 in the third direction 98 to load the substrate W. The first plate 483 may be moved up to a distance spaced apart from the second plate 484. Simultaneously, the second plate 484 may be raised in the third direction 96 by force of the elastic member 470 to lift the guide ring support 462. The guide ring support 462 is raised and positioned at the process position P2. When the guide ring support 462 is raised, the second link 4542 is also raised. For example, the second link 4542 may be rotated in the counterclockwise direction with respect to a coupling portion with the first link 4541. Simultaneously, the second link 4542 pulls the first link 4541 in a direction toward the spin chuck 451. The chuck pin 452 is moved to the support position C1 by the movement of the first link 4541. The chuck pin 452 receives the substrate W from the support pin 451a and supports an end portion of the substrate W.

When the substrate W is loaded, the liquid supply unit 440 supplies the first treatment liquid to the upper surface of the substrate W and supplies the second treatment liquid to the bottom surface of the substrate W. The second driver 482 rotates the spin chuck 451 simultaneously with or after supplying the first treatment liquid and the second treatment liquid. Accordingly, the substrate W is subjected to liquid treatment. The first treatment liquid and the second treatment liquid may be scattered from the substrate W. The scattered first treatment liquid and second treatment liquid are separated and guided by the guide ring 461, and are separated and recovered from the cup body 420.

When the substrate treatment is completed, the substrate W is unloaded. The unloading of the substrate W is performed through a process opposite to the loading of the substrate W. The unloading of the substrate W is performed in the same process as the process performed to load the substrate onto the spin chuck 451. When the guide ring unit 460 is again positioned at the waiting position P1 and the chuck pin 452 is positioned at the spaced position C2, the substrate W is unloaded by the transfer robot 320.

According to the exemplary embodiment of the present invention, the separation and recovery rate of the treatment liquid may be improved by installing the guide ring unit 460 between the spin chuck 451 and the cup body 420. Furthermore, even if the guide ring unit 460 is provided, when the substrate W is loaded into the support unit 450 or unloaded from the support unit 450, the chuck pin 452 is moved to the spaced position C2 and at the same time, the guide ring unit 450 is moved to the lower portion of the spin chuck 451, and thus the interference between the guide ring unit 450 and the transfer robot 320 may be removed.

Furthermore, since the chuck pin 452 and the guide ring unit 460 are simultaneously driven by one first driver 481 without the installation of a separate driver, the complexity of the structure may be avoided.

Furthermore, since the elastic member 470 applies elastic force to the guide ring unit 460 in the third direction 96, it is possible to prevent the guide ring unit 460 from being lowered or the chuck pin 452 from moving away from the support position C1.

In addition, a back nozzle may be provided to the support unit 450 because the support unit 450 is fixed during the transfer process of the substrate W.

In the above-described example, the present invention has been described based on the case where only the first nozzle is provided as the nozzle for supplying the treatment liquid to the upper surface of the substrate W as an example. However, the present invention is not limited thereto, and a plurality of nozzles may be provided to supply a treatment liquid to the upper surface of the substrate W. In this case, the added nozzle may supply another type of treatment liquid to the substrate. In addition, the added nozzles are supported by different arms, and may be moved independently. Optionally, the first nozzle 452 and the added nozzle may be mounted on the same arm and moved simultaneously.

In addition, in the above-described example, the present invention has been described based on the case where the substrate W is treated with the treatment liquid as an example. However, the present invention is not limited thereto, and a configuration of injecting drying gas onto the substrate W may be further added so as to dry the treatment liquid.

Also, in the above example, the present invention has been described based on the case where the extension portion 462b is provided integrally with the guide ring support 462 as an example. However, the present invention is not limited thereto, and the extension portion 462b may be provided as a separate configuration and coupled to the guide ring support 462.

It should be understood that exemplary embodiments have been disclosed herein, and other modifications may be possible. Individual elements or features of a particular exemplary embodiment are generally not limited to the particular exemplary embodiment, but may be interchangeable and used in selected exemplary embodiments, if applicable, if not specifically illustrated or described. Such modifications should not be considered outside the spirit and scope of the present disclosure, and all such modifications obvious to those skilled in the art are intended to be included within the scope of the following claims.

What is claimed is:

1. An apparatus of processing a substrate, the apparatus comprising:
a cup body having a treatment space therein;
a support unit for supporting a substrate within said treatment space; and
a guide ring unit located in the treatment space, surrounding the substrate placed on the support unit, and guiding a treatment liquid scattered from the substrate to the cup body;
a liquid supply unit for supplying the treatment liquid to the substrate; and
a driver,
wherein the support unit includes:
a spin chuck on which the substrate is placed and which is rotatable; and
a chuck pin provided to the spin chuck and supporting the substrate on a side portion of the substrate,
the guide ring unit is provided to be movable relative to the spin chuck in an up and down direction,
the chuck pin is provided to be movable between a support position supporting an end of the substrate placed on the spin chuck and a spaced position spaced apart from the end of the substrate placed on the spin chuck, and
the driver moves the guide ring relative to the spin chuck and simultaneously moves the chuck pin between the support position and the spaced position.

2. The apparatus of claim 1, wherein the guide ring is movable between a process position and a waiting position,
the process position is a position where a relative height with respect to the spin chuck is higher than the waiting position, and
the chuck pin is provided to move from the spaced position to the support position when the guide ring is moved from the waiting position to the process position.

3. The apparatus of claim 2, wherein the chuck pin is provided to move from the support position to the spaced position when the guide ring is moved from the process position to the waiting position.

4. The apparatus of claim 1, wherein the cup body includes:
an inner cup;
an intermediate cup surrounding the inner cup; and
an outer cup surrounding the intermediate cup, and
the guide ring is provided to guide the treatment liquid scattered from the substrate to a space selected from a space between the inner cup and the intermediate cup and a space selected between the intermediate cup and the outer cup.

5. The apparatus of claim 3, further comprising:
a pin drive link connected to the driver,
wherein the chuck pin is moved by the pin drive link,
the pin drive link includes:
a first link to which the chuck pin is coupled; and
a second link pivotally coupled to the first link and installed in the guide ring.

6. The apparatus of claim 3, further comprising:
an elastic member,
wherein the elastic member is installed under the guide ring support and is provided in a compressed state at the process position to apply elastic force toward the guide ring.

7. The apparatus of claim 1, wherein the guide ring includes:
an upper ring;
a lower ring facing the upper ring in an up and down direction; and
an intermediate ring disposed between the upper ring and the lower ring, and
the upper ring, the intermediate ring, and the lower ring are fixed to each other by a fixing rod.

8. The apparatus of claim 1, wherein the driver and the guide ring unit are separably provided.

9. The apparatus of claim 1, wherein the treatment liquid is provided as a first treatment liquid or a second treatment liquid different from the first treatment liquid,
the liquid supply unit includes:
a first nozzle for discharging the first treatment liquid to an upper surface of the substrate; and
a second nozzle for discharging the second treatment liquid to a lower surface of the substrate, and
the first treatment liquid and the second treatment liquid are separated and recovered by the guide ring.

10. An apparatus of processing a substrate, the apparatus comprising:
a cup body having a treatment space therein;
a support unit for supporting a substrate within said treatment space; and
a guide ring unit located in the treatment space, surrounding the substrate placed on the support unit, and guiding a treatment liquid scattered from the substrate to the cup body;
a liquid supply unit for supplying the treatment liquid to the substrate; and
a first driver for driving the guide ring,
wherein the guide ring unit includes:
a guide ring for guiding a treatment liquid scattered from the substrate to the cup body; and
a guide ring support in which the guide ring is installed and to which the first driver is connected,
the support unit includes:
a spin chuck on which the substrate is placed and which is rotatable; and
a chuck pin provided to the spin chuck and supporting the substrate on a side portion of the substrate; and
a pin drive link which is coupled with the chuck pin, and which drives the chuck pin to approach or move away from the substrate supported by the spin chuck, and
the pin drive link operates in conjunction with driving of the first driver.

11. The apparatus of claim 10, wherein the chuck pin moves in a direction approaching the substrate placed on the spin chuck when the guide ring is raised, and moves in a direction away from the substrate placed on the spin chuck when the guide ring is lowered.

12. The apparatus of claim 11, wherein the pin drive link includes:
a first link coupled with the chuck pin; and
a second link connected to the first link and installed on the guide ring support, and
the first link and the second link, and the second link and the guide ring support are pivotally coupled to each other.

13. The apparatus of claim 12, further comprising:
an elastic member,
wherein the elastic member is installed under the guide ring support and provided in a compressed state at the process position to apply elastic force toward the guide ring support.

14. The apparatus of claim 10, wherein the support unit includes:
a rotating shaft for supporting the spin chuck at a center of a bottom surface of the spin chuck;
a second driver for providing rotational force to the rotating shaft;
a first plate to which the guide ring support is connected and which is provided to surround the rotating shaft; and
a second plate connected to the first driver and provided to surround the first plate, and
the first plate is formed with a first protrusion and a first groove,
the second plate is formed with a second groove corresponding to a shape and a position of the first protrusion, and a second protrusion corresponding to a shape and a position of the first groove,
when viewed from above, the first groove and the second groove are provided so that partial areas thereof overlap as the first plate rotates, and
when the spin chuck is rotated, the first plate and the second plate are spaced apart from each other.

15. The apparatus of claim 10, wherein the chuck pins are provided in plural,
the plurality of chuck pins is coupled to the plurality of first links, respectively,
the plurality of first links is connected to the plurality of second links, respectively, and
the plurality of second links is installed on the guide ring support.

16. The apparatus of claim 10, wherein the treatment liquid is provided as a first treatment liquid or a second treatment liquid different from the first treatment liquid,
the cup body includes:
an inner cup surrounding the support unit;
an intermediate cup surrounding the inner cup; and
an outer cup surrounding the intermediate cup,
the inner cup, the intermediate cup, and the outer cup are stacked on each other,
the inner cup provides a first inlet through which the second treatment liquid is scattered,
the inner cup and the intermediate cup are combined with each other to provide a second inlet through which the first treatment liquid or the second treatment liquid is scattered,
the intermediate cup and the outer cup are combined with each other to provide a third inlet through which the first treatment liquid is scattered,
the guide ring includes:
an upper ring;
a lower ring facing the upper ring in an up and down direction; and
an intermediate ring disposed between the upper ring and the lower ring, and
the upper ring, the intermediate ring, and the lower ring are fixed to each other by a fixing rod, and are positioned so that during the treatment of the substrate, the first treatment liquid or the second treatment liquid are scattered to the first inlet, the second inlet, or the third inlet.

17. The apparatus of claim 16, wherein the liquid supply unit includes:
a first nozzle for discharging the first treatment liquid to an upper surface of the substrate; and
a second nozzle for discharging the second treatment liquid to a lower surface of the substrate.

18. An apparatus of processing a substrate, the apparatus comprising:
a cup body having a treatment space therein;
a support unit for supporting a substrate within said treatment space; and
a guide ring unit located in the treatment space, surrounding the substrate placed on the support unit, and guiding a treatment liquid scattered from the substrate to the cup body;
a liquid supply unit including a first nozzle discharging a first treatment liquid to an upper surface of the substrate, and a second nozzle discharging a second treatment liquid to a bottom surface of the substrate, and
a drive unit for driving the guide ring unit and the support unit,
wherein the support unit includes:
a spin chuck on which the substrate is placed and which is rotatable; and
a chuck pin provided to the spin chuck and supporting the substrate on a side portion of the substrate;
a rotating shaft for supporting the spin chuck at a center of a bottom surface of the spin chuck; and
a pin drive link which is coupled with the chuck pin, and which drives the chuck pin to approach or move away from the substrate supported by the spin chuck, and
the guide ring unit includes:
a guide ring for guiding a treatment liquid scattered from the substrate to the cup body; and
a guide ring support in which the guide ring is installed and to which a first driver is connected,
the drive unit includes:
a first driver for driving the guide ring unit;
a second driver for driving the support unit;
a first plate to which the guide ring support is connected and which is provided to surround the rotating shaft; and
a second plate connected to the first driver and provided to surround the first plate, and
the pin drive link includes:
a first link coupled with the chuck pin; and
a second link connected to the first link and installed on the guide ring support,
the first link and the second link are provided to pivot at a connection point where the first link and the second link are connected,
the second link and the guide ring support are provided to pivot at an installation point where the second link is installed on the guide ring support,
when the guide ring unit is lowered, the chuck pin moves in a direction away from the substrate, and when the guide ring unit is raised, the chuck pin moves in a direction close to the substrate,
the first plate is formed with a first protrusion and a first groove,
the second plate is formed with a second groove corresponding to a shape and a position of the first protrusion, and a second protrusion corresponding to a shape and a position of the first groove, and
when viewed from above, the first groove and the second groove are provided so that partial areas thereof overlap as the first plate rotates.

19. The apparatus of claim 18, further comprising:
an elastic member,
wherein the elastic member is installed under the guide ring support and provided in a compressed state at the process position to apply elastic force toward the guide ring support.

20. The apparatus of claim 19, wherein the cup body includes:
an inner cup surrounding the support unit;
an intermediate cup surrounding the inner cup; and
an outer cup surrounding the intermediate cup,
the inner cup, the intermediate cup, and the outer cup are stacked on each other,
the inner cup provides a first inlet through which the second treatment liquid is scattered,
the inner cup and the intermediate cup are combined with each other to provide a second inlet through which the first treatment liquid or the second treatment liquid is scattered,
the intermediate cup and the outer cup are combined with each other to provide a third inlet through which the first treatment liquid is scattered,
the guide ring includes:
an upper ring;
a lower ring facing the upper ring in an up and down direction; and
an intermediate ring disposed between the upper ring and the lower ring, and
the upper ring, the intermediate ring, and the lower ring are fixed to each other by a fixing rod, and are positioned so that during the treatment of the substrate, the first treatment liquid or the second treatment liquid are scattered to the first inlet, the second inlet, or the third inlet.
